(19) United States
(12) Patent Application Publication
(10) Pub. No.: US 2009/0057800 A1
(43) Pub. Date: Mar. 5, 2009

(54) SMALL-SIZE MODULE

(75) Inventors: Daigo Suzuki, Yokohama-shi (JP); Makoto Aoki, Fukaya-shi (JP)

Correspondence Address: KNOBBE MARTENS OLSON & BEAR LLP, 2040 MAIN STREET, FOURTEENTH FLOOR, IRVINE, CA, 92614, US

(73) Assignee: KABUSHIKI KAISHA TOSHIBA, Tokyo (JP)

(21) Appl. No.: 12/200,733

(22) Filed: Aug. 28, 2008

(30) Foreign Application Priority Data
Aug. 30, 2007 (JP) 2007-224366

(51) Int. Cl. H01L 31/02

(52) U.S. Cl. 257/434; 257/690; 257/E31.11

(57) ABSTRACT

According to one embodiment, a small-size module an IC chip having leads provided on at least two sides of the IC chip, a circuit substrate having a component mounting face, plural pairs of auxiliary substrates which are disposed between the component mounting face of the circuit substrate and the IC chip so as to nip the leads extending from each of the two sides and mount the IC chip on the component mounting face of the circuit substrate, and a through conductor which is provided in at least one of the pair of the auxiliary substrates and bonded conductively to the nipped leads to connect the leads to the circuit substrate.

### CROSS-REFERENCE TO RELATED APPLICATIONS

This application is based upon and claims the benefit of priority from Japanese Patent Application No. 2007-224366, filed Aug. 30, 2007, the entire contents of which are incorporated herein by reference.

### BACKGROUND

1. Field

One embodiment of the present invention relates to a small-size module in which an IC chip having leads extending from its IC chip main body is mounted on a circuit substrate.

2. Description of the Related Art

When constructing an electronic circuit module by mounting a small-size IC chip having plural leads extending laterally from both sides of its IC chip main body on a circuit substrate, conventionally, the leads are heated directly and bonded to the circuit substrate.

In IC chip mounting means for mounting the IC chip on the circuit substrate by heating the leads directly, some measures for avoiding an influence of excessive heat upon the IC chip main body caused by the heating of the leads is necessary. Conventionally, the leads are extended directly or indirectly when they are bonded in order to avoid the influence of the excessive heat upon the IC chip main body due to heating of the leads. However, such an IC chip mounting measure has a problem in miniaturizing of the aforementioned module because the IC chip mounting space is expanded by the extended leads.

As mounting means for the IC chip having the leads extending laterally from its IC chip package, conventionally, there exists a stack type mounting structure for mounting the IC chip on a system substrate via clip type leads (or side boards) by heating the leads directly. See Jpn. Pat. Appln. KOKAI Publication Nos. 2002-305284 and 6-097622, for example.

As described above, the IC chip mounting means for mounting the IC chip on the circuit substrate by heating the extended leads directly has a problem in miniaturizing of the module because the mounting space for the IC chip is expanded.

### BRIEF DESCRIPTION OF THE SEVERAL VIEWS OF THE DRAWINGS

A general architecture that implements the various features of the invention will now be described with reference to the drawings. The drawings and the associated descriptions are provided to illustrate embodiments of the invention and not to limit the scope of the invention.

FIG. 1 is a partially sectional side view showing the structure of a small-size module according to a first embodiment of the present invention;

FIG. 2 is a plan view showing the structure of the small-size module according to the first embodiment;

FIG. 3 is a perspective view showing the structure of the small-size module according to the first embodiment;

FIG. 4 is a diagram showing a manufacturing process for the small-size module according to the first embodiment;

FIG. 5 is a diagram showing a manufacturing process for the small-size module according to the first embodiment;

FIG. 6 is a partially sectional side view showing the structure of the small-size module according to the first embodiment of the present invention;

FIG. 7 is a partially sectional side view showing the structure of a small-size module according to a second embodiment of the present invention;

FIG. 8 is a partially sectional side view showing the structure of a small-size module according to a third embodiment of the present invention;

FIG. 9 is a partially sectional side view showing the structure of a small-size module according to a fourth embodiment of the present invention;

FIG. 10 is a partially sectional side view showing the structure of a small-size module according to a fifth embodiment of the present invention;

FIG. 11 is a partially sectional side view showing the structure of a small-size module according to a sixth embodiment of the present invention;

FIG. 12 is a diagram showing a manufacturing process and installation process of a terminal stud substrate according to the above respective embodiments;

FIG. 13 is a diagram showing a manufacturing process and installation process of the terminal stud substrate according to the above respective embodiments;

FIG. 14 is a diagram showing a manufacturing process and installation process of the terminal stud substrate according to the above respective embodiments;

FIG. 15 is a diagram showing a manufacturing process and installation process of the terminal stud substrate according to the above respective embodiments; and

FIG. 16 is a diagram showing a manufacturing process and installation process of the terminal stud substrate according to the above respective embodiments.

### DETAILED DESCRIPTION

Various embodiments according to the present invention will be hereinafter described with reference to the accompanying drawings. In general, according to one embodiment of the invention, a small-size module comprising: an IC CHIP having leads on at least two sides; a circuit substrate having a component mounting face; plural pairs of auxiliary substrates whIC chiph are disposed between the component mounting face of the circuit substrate and the IC CHIP so as to nip the leads of the each side and mount the IC CHIP on the component mounting face of the circuit substrate; and a through conductor whIC chiph is provided in at least one of the pair of the auxiliary substrates and bonded conductively to the nipped leads to connect the leads to the circuit substrate.

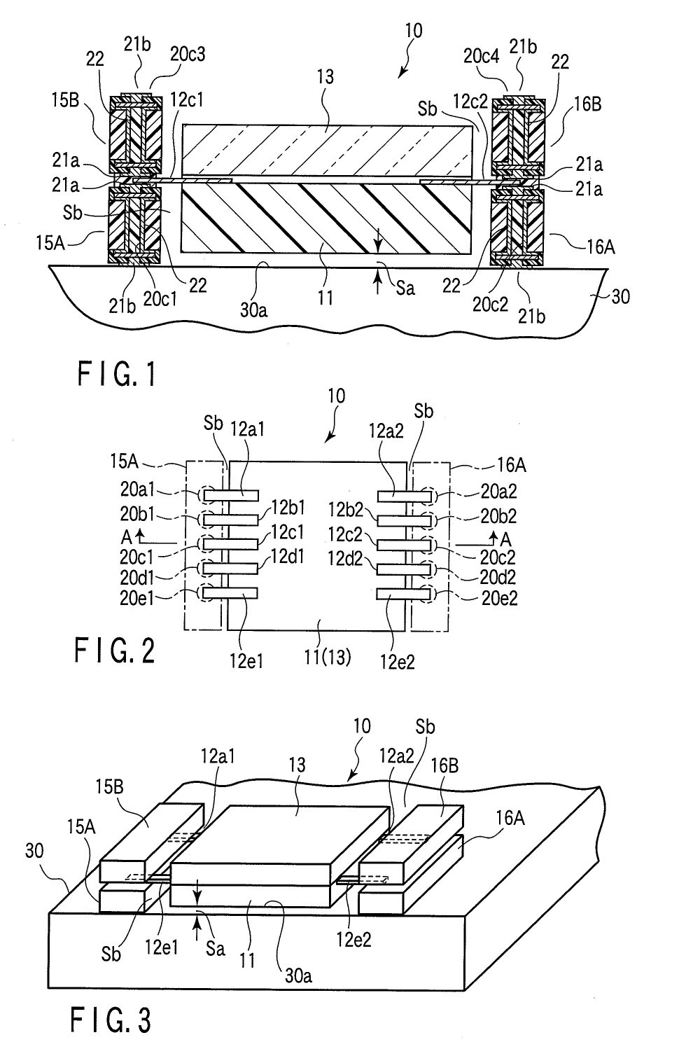

FIGS. 1 to 6 show the structure of a small-size module according to a first embodiment of the present invention.

The small-size module according to one embodiment of the present invention is constituted of an IC chip in which a plurality of leads extending laterally from the an IC chip main body are arranged, and auxiliary substrates arranged next to the IC chip main body and forming intermediate members which nip the leads from upper and under side of the leads so as to mount the IC chip on a component mounting face of a circuit substrate.

As shown in FIGS. 1 to 3, the basic structure of the small-size module according to the first embodiment of the present invention includes an IC chip 10 having a plurality of leads (10 leads, in this case) 12a1, 12a2, . . . 12e2 extending from one or more of sides (two sides, in this case), a circuit substrate 30 having a component mounting face 30a, and a plurality of pairs (two pairs, in this case) of auxiliary substrates (hereinafter referred to as terminal stud substrates) 15A, 15B, 16A, 16B. The terminal stud substrates 15A and 15B are stacked successively beside the IC chip main body on the component mounting face 30a of the circuit substrate 30 for supporting one side of the IC chip 10 by nipping the leads 12a1, 12b1, 12c1, 12d1 and 12e1 extended from one side of the IC chip 10. In the similar manner, the terminal stud substrates 16A and 16B are stacked successively beside the IC chip main body on the component mounting face 30a of the circuit substrate 30 for supporting another opposite side of the IC chip 10 by nipping the leads 12a2, 12b2, 12c2, 12d2 and 12e2 extended from the opposite side of the IC chip 10. Thus, the IC chip 10 is mounted on the component mounting face 30a of the circuit substrate 30. A plurality of through conductors (ten conductors 20a1, 20a2, . . . 20e2, in this case) which are provided in the terminal stud substrates 15A and 16A mounted on the circuit substrate 30 are bonded conductively to the nipped leads 12a1, 12a2, . . . 12e2 so that the leads 12a1, 12a2, . . . 12e2 are connected to the circuit substrate 30. Further, similar through conductors are formed in the upper side terminal stud substrates 15B and 16B to be connected to the nipped leads 12a1, 12a2, . . . 12e2. In FIG. 1, only through conductors 20c3, 20c4 formed in the upper side terminal stud substrates 15B and 16B corresponding to the conductors 20c1, 20c2 are shown. Thus, a plurality of through conductors corresponding to the conductors formed in the lower side terminal stud substrates 15A, 16A are formed in the upper side terminal stud substrates 15B and 16B. In FIG. 2, the upper side terminal stud substrates 15B and 16B and the glass plate 13 are not shown for the sake of simplicity.

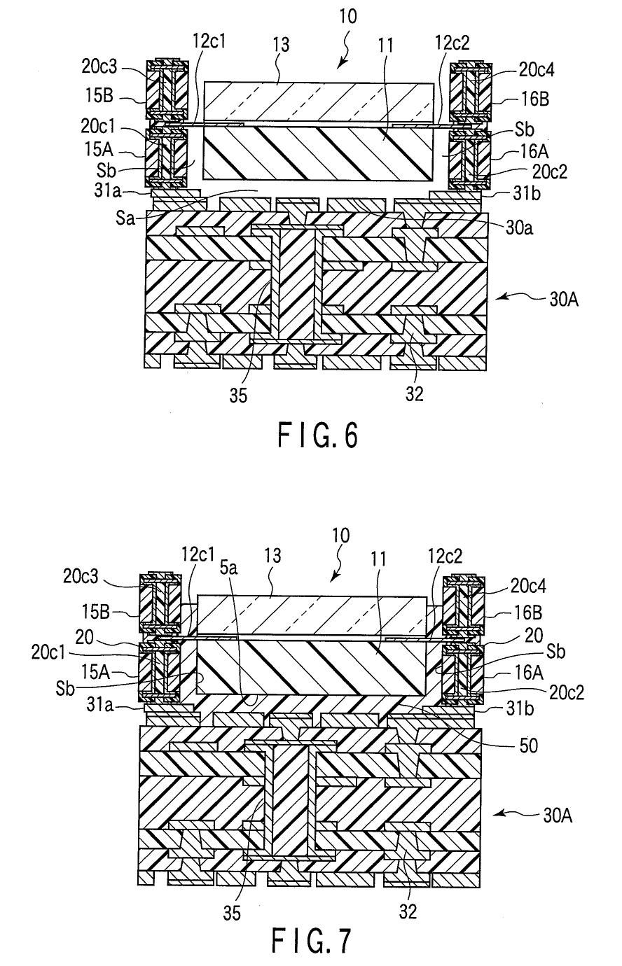

The IC chip 10 is supported by the terminal stud substrates 15A, 15B, 16A, 16B with a predetermined gap Sa with respect to the component mounting face 30a of the circuit substrate 30 as shown in FIGS. 1 and 3. This IC chip 10 has a rectangular IC chip main body 11 and the plurality of leads 12a1, 12a2, . . . 12e2 extending from two opposite parallel sides of the IC chip main body 11 as shown in FIG. 2. As shown in FIG. 3, the respective leads 12a1, 12a2, . . . 12e2 extending from both sides of the IC chip main body 11 are nipped by the pairs of the terminal stud substrates 15A, 15B, and 16A, 16B provided independently on each side from which the leads 12a1, 12a2, . . . 12e2 are extended, so that the IC chip 10 is mounted on the component mounting face 30a of the circuit substrate 30 by the terminal stud substrates 15A, 15B and 16A, 16B which serve as an intermediate member. The terminal stud substrates 15A, 16A are soldered to component bonding electrodes (see reference numerals 31a, 31b shown in FIG. 6) provided on the component mounting face 30a of the circuit substrate 30 so that they are fixed on the component mounting face 30a.

As described above, the IC chip 10 is mounted on the component mounting face 30a of the circuit substrate 30 with the two pairs of the terminal stud substrates 15A, 15B and 16A, 16B as intermediate members. In the meantime, in FIG. 3, some of the leads 12a1, . . . 12e1, . . . 12e2 are omitting for the sake of simplicity. In this embodiment, a solid state image pickup device having several millimeter square in which a transparent member (glass) 13 is disposed on the surface of the IC chip main body 11 is exemplified as the IC chip 10. Further, a small-size IC chip having other structure without the transparent member 13 may be adopted.

Of the terminal stud substrates 15A, 15B, 16A, 16B provided on both sides of the IC chip main body 11, the terminal stud substrates 15A, 16A to be bonded to the component mounting face 30a of the circuit substrate 30 are projected from the bottom face (bottom face of the IC chip main body 11) of the IC chip 10 as shown in FIG. 1 and, as shown in FIG. 3, the terminal stud substrates 15A, 16A are mounted on the component mounting face 30a of the circuit substrate 30. Consequently, as shown in FIGS. 1 and 3, a predetermined gap Sa (also shown in FIG. 6) is formed between the bottom face of the IC chip 10 and the component mounting face 30a of the circuit substrate 30. Further, the terminal stud substrates 15A, 15B, 16A, 16B nip each front end portion of the leads 12a1, 12a2, . . . 12e2 extending laterally from the IC chip main body 11 so that gaps Sb (see also shown in FIG. 6) communicating with the aforementioned gap Sa is formed between both sides of the IC chip main body 11 and the terminal stud substrates 15A, 15B and 16A, 16B.

The terminal stud substrates 15B, 16B provided on both sides of the IC chip main body 11 are projected from the surface of the transparent member (glass plate) 13 as shown FIG. 1 and projecting portions of the terminal stud substrates 15B, 16B form a mounting guide for an optical member of an imaging device (not shown), when the IC chip 10 is formed as the solid state image pickup device.

The terminal stud substrates 15A, 15B, 16A, 16B are each formed of a four-layer structured printed wiring board. The four-layer structured printed wiring board is cut into a plurality of small pieces to manufacture as a plurality of terminal stud substrates. One of the small pieces (terminal stud substrates) is prepared as the terminal stud substrate 15A which contains a plurality of the through conductors (terminal studs) 20a1, 20a2, . . . 20e2 to be bonded to the leads 12a1, 12c1, . . . 12e1 of the IC chip 10. Another small piece is used as the terminal stud substrate 16A containing the through conductors 20a2, . . . 20e2 to be bonded to the leads 12a2, . . . 12e2, for example.

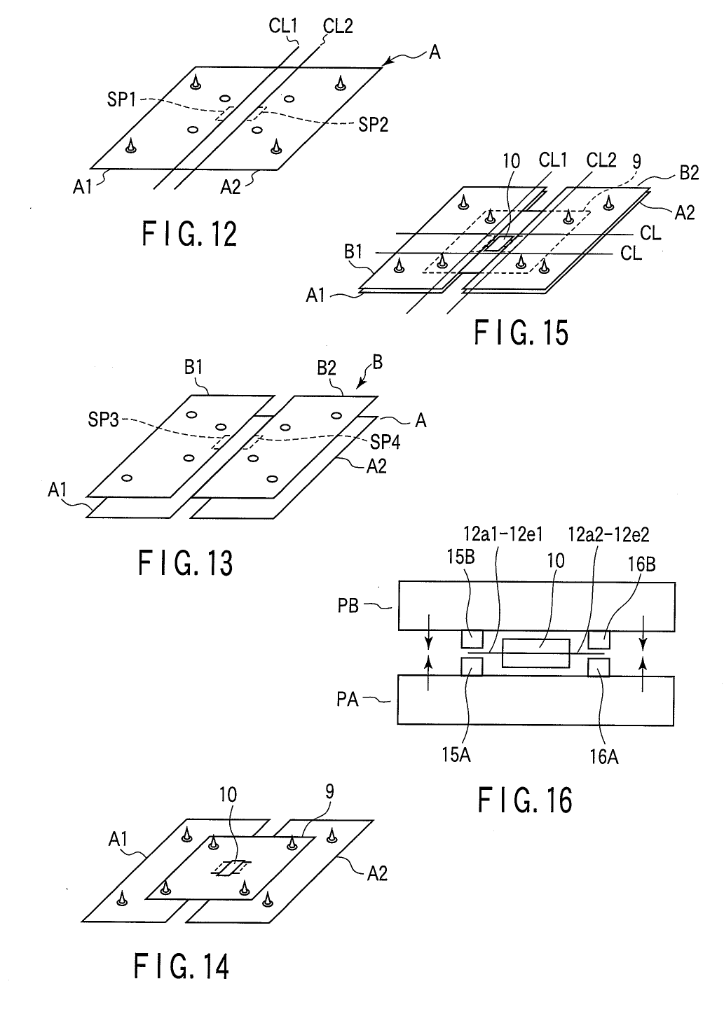

Each of the through conductors 20a1, 20a2, . . . 20e2 is constituted of metal bumps 21a and 21b formed at both end portions of the through conductors 20a1, 20a2, . . . 20e2 at surface portions of each of the four-layer structured printed wiring boards or four-layer structured terminal stud substrates 15A, 15B, 16A, 16B. Through vias 22 are formed in the through holes at each of the through conductors 20a1, 20a2, . . . 20e2 formed in the substrates 15A, 15B, 16A, 16B, so that the metal bumps 21a and 21b are connected via the through vias 22 at each of the through conductors 20a1, 20a2, . . . 20e2. A process for producing the terminal stud substrates 15A, 15B, 16A, 16B of the small piece from the printed wiring board will be described later with reference to FIGS. 12 and 13.

As shown in FIGS. 1 to 3, the leads 12a1, 12a2, . . . 12e2 extending from two sides of the IC chip main body 11 are supported by pairs of the terminal stud substrates 15A, 15B and 16A, 16B provided independently on each side, so that the IC chip 10 is mounted on the component mounting face 30a of the circuit substrate 30 with the pairs of the substrates serving as intermediate members.

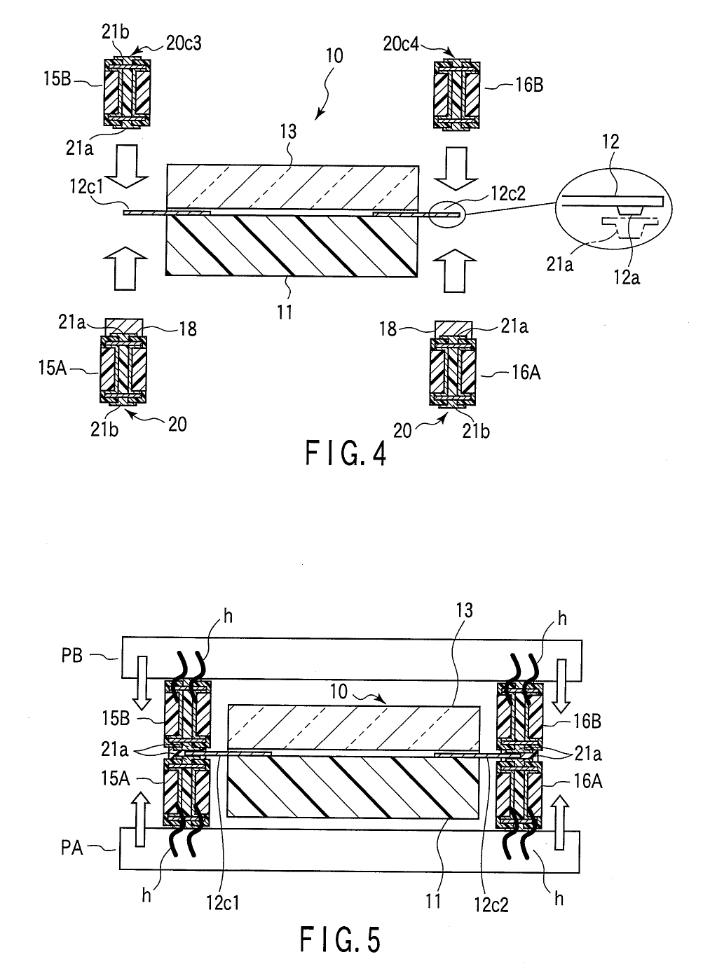

FIGS. 4 and 5 show thermal compression bonding means for the leads 12a1, 12a2, . . . 12e2 of the IC chip 10 and the terminal stud substrates 15A, 15B, 16A, 16B. FIGS. 4 and 5 show a case where the through conductors 20c1, 20c3 and through conductors 20c2 and 20c4 are connected to the leads 12c1 and 12c2 as an example corresponding to FIG. 1. Before the thermal compression bonding of the terminal stud substrates 15A, 15B and 16A, 16B, as shown in FIG. 4, the two pairs of the upper and lower terminal stud substrates 15A, 15B and 16A, 16B, constructed of the small piece of the printed wiring board, are prepared. The through conductors 20c1, 20c3 and 20c2, 20c4 corresponding to the leads 12c1 and 12c2 of the IC chip 10 are provided on the terminal stud substrates 15A, 15B and 16A, 16B. Another through conductors may be provided on the substrates 15A . . . 16b in the similar manner. After the metal bumps (for example, gold (Au) bump) 21a are formed on a lead bonding face of the terminal stud substrates 15A, 15B and 16A, 16B, anisotropic conductive films (ACF), anisotropic conductive pastes (ACP), non conductive films (NCF) or non conductive pastes (NCP) are affixed, as conductive bonding members 18, to the lead bonding face of the terminal stud substrate 15A and 16A on one side of each pair of substrates 15A, 15B and 16A and 16B. After that, as shown in FIG. 5, with the leads 12c1 and 12c2 (together with the remaining eight leads shown in FIG. 2) nipped by the terminal stud substrates 15A, 15B and 16A, 16B, the terminal stud substrates 15A, 15B and 16A, 16B are heated and pressed with a heating/pressure forming machine (PA, PB). At the time of this heating/pressure application, the leads 12c1, 12c2 and the remaining leads are heated with the terminal stud substrates 15A, 15B, 16A, 16B serving as a heat conduction path h and then, the terminal stud substrates 15A, 15B and the terminal stud substrates 16A, 16B are pressed together via the conductive bonding members 18 (ACF, ACP, NCF or NCP), and consequently, the respective leads 12a1, 12a2, . . . 12e2 of the IC chip main body 11 are thermally compression bonded to the terminal stud substrates 15A, 15B and 16A, 16B. By this thermal compression bonding, the two pairs of the terminal stud substrates 15A, 15B and 16A, 16B are provided integrally beside the IC chip main body 11 with the leads 12a1, 12a2, . . . 12e2 coupled conductively with the through conductors 20a1, 20a2, . . . 20e2 of the terminal stud substrates 15A, 15B and 16A, 16B.

FIG. 6 shows an example that the IC chip 10, in which each of the pairs of the terminal stud substrates 15A, 15B and 16A, 16B is provided beside two parallel opposite sides of the IC chip main body 11, is mounted on a multilayer circuit substrate. FIG. 6 exemplifies a multilayer circuit substrate having a six-layer structure provided with interlayer connecting vias 32, an interlayer through via 35 and the like. According to the IC chip mounting structure shown in FIG. 6, the through conductors (conductors 20c1, 20c2 are shown in the FIG. 6) provided in the terminal stud substrates 15A, 16A are soldered to component connecting electrodes 31a, 31b provided on the component mounting face 30a of a multilayer circuit substrate 30A, so that the IC chip 10 is mounted on the component mounting face 30a of the multilayer circuit substrate 30A with the terminal stud substrates 15A, 16A serving as intermediate members. The terminal stud substrates 15A, 16A are projected from the bottom face of the IC chip 10. When the IC chip 10 is mounted on the component mounting face 30a of the circuit substrate 30A with the terminal stud substrates 15A, 16A serving as intermediate members, a predetermined gap Sa is formed between the bottom face of the IC chip 10 and the component mounting face 30a of the circuit substrate 30A. Further, each pair of the terminal stud substrates 15A, 15B and 16A, 16B nips the front end portions of the leads (leads 12c1, 12c2 are shown) extending laterally from the opposite sides of the IC chip main body 11, so as to form a gap Sb communicating with the aforementioned gap Sa between both sides of the IC chip main body 11 and the terminal stud substrates 15A, 15B and 16A, 16B.

In the mounting structure of the IC chip 10 with the terminal stud substrates 15A, 16A serving as intermediate members, the leads 12a1, 12a2, . . . 12e2 (only leads 12c1, 12c2 are shown) of the IC chip 10 are thermally compression bonded via the pairs of the terminal stud substrates 15A, 15B and 16A, 16B and soldered to the component mounting face 30a of the circuit substrate 30A via the terminal stud substrates 15A, 16A. Thus, as compared with a structure in which the leads are bonded to a circuit substrate by heating directly, thermal damage given to the IC chip main body 11 when the leads are bonded by heating can be reduced considerably, according to the embodiment. Further, as compared with conventional mounting means for avoiding a thermal influence upon the IC chip main body by extending the lead directly or indirectly, the length of the lead extending from the sides of the IC chip main body 11 can be reduced. Consequently, a mounting space of the IC chip 10 on the component mounting face 30a of the circuit substrate 30A can be reduced. Therefore, a smaller size of the module can be achieved easily. Further, the IC chip 10 is mounted on the component mounting face 30a of the circuit substrate 30 or 30A with the respective leads 12a1, 12a2, . . . 12e2 of the IC chip 10 supported by the pairs of the terminal stud substrates 15A, 15B and 16A, 16B provided independently on each side of the IC chip main body 11. As a result, as compared with a single plate (frame) structure provided with a recess which serves as a relief hole, distortion due to residual stress can be reduced, thereby maintaining a stabilized circuit bonding condition resisting thermal deformation, mechanical stress and the like of the circuit substrate after the IC chip is mounted on a circuit substrate.

FIGS. 7 to 11 show other embodiments of the present invention based on the basic chip structure shown in FIGS. 1 to 6. In the meantime, in FIGS. 7 to 11, like reference numerals are attached to the same components as those of the first embodiment shown in FIGS. 1 to 6 and description thereof is omitted.

FIG. 7 shows the structure of a small-size module according to a second embodiment of the present invention. According to the small-size module structure of the second embodiment shown in FIG. 7, the aforementioned gaps Sa, Sb formed between the bottom face of the IC chip 10 and the component mounting face 30a of the multilayer circuit substrate 30A and between both sides of the IC chip main body 11 and the terminal stud substrates 15A, 15B and 16A, 16B as shown in FIG. 6 are filled with underfill 50 so as to seal the IC chip main body 11 of the IC chip 10 and the leads 12c1, 12c2 in the gap portion between the terminal stud substrates 15A, 15B and the terminal stud substrates 16A, 16B with resin. Due to such an IC chip mounting structure, the mounting space of the IC chip 10 on the component mounting face 30a of the multilayer circuit substrate 30A can be reduced and the mounting strength of the IC chip 10 with the terminal stud substrates 15A, 15B, 16A, 16B serving as intermediate members can be intensified as compared with the structure shown in FIG. 6.

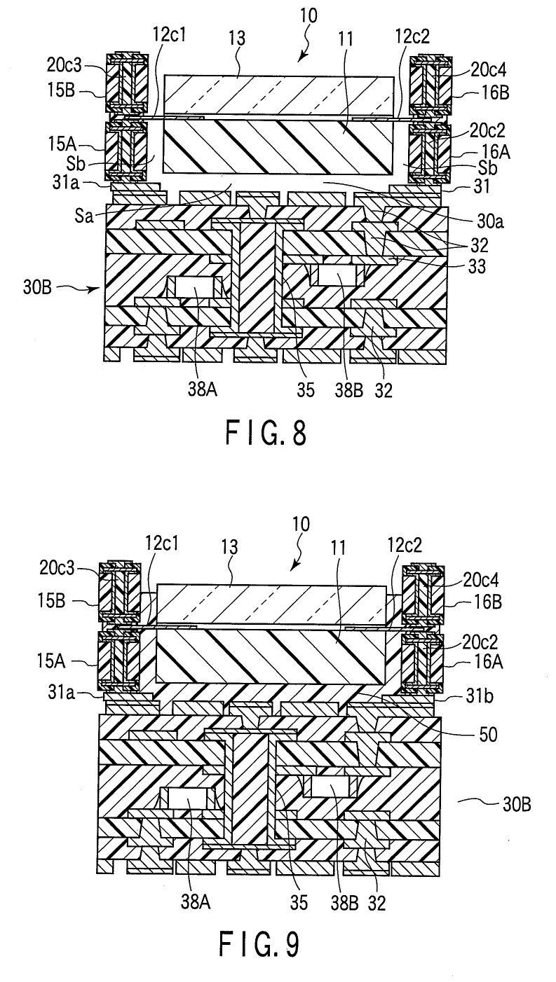

FIG. 8 shows the structure of a small-size module according to a third embodiment of the present invention. According to the small-size module structure of the third embodiment shown in FIG. 8, the IC chip 10 is mounted in a component-incorporating circuit substrate 30B and the leads such as a lead 12c2, for example, of the IC chip 10 are connected to an incorporated component 38B through the through conductors 20c2, for example, of the terminal stud substrate 16A, the component bonding electrode 31b, vias 32 and a wiring 33. With such a circuit connection structure, the mounting space of the IC chip 10 on the component mounting face 30a of the component-incorporating circuit substrate 30B can be reduced and the component mounting density of the small-size module can be intensified.

FIG. 9 shows the structure of a small-size module according to a fourth embodiment of the present invention. According to the small-size module structure of the fourth embodiment shown in FIG. 9, the aforementioned gap portions Sa, Sb shown in FIG. 8 formed between the bottom face of the IC chip 10 and the component mounting face 30a of the component-incorporating circuit substrate 30B and between both sides of the IC chip main body 11 and the terminal stud substrates 15A, 15B and 16A, 16B are filled with underfill resin 50, so that the IC chip main body 11 of the IC chip 10 and the leads such as leads 12c1, 12c2 are sealed in the gap Sa, Sb portion between the terminal stud substrates 15A, 15B and the terminal stud substrates 16A, 16B. With such an IC chip mounting structure, miniaturization of the circuit substrate 30B in the small-size module and intensified density of the component mounting can be achieved and the IC chip mounting strength can be improved.

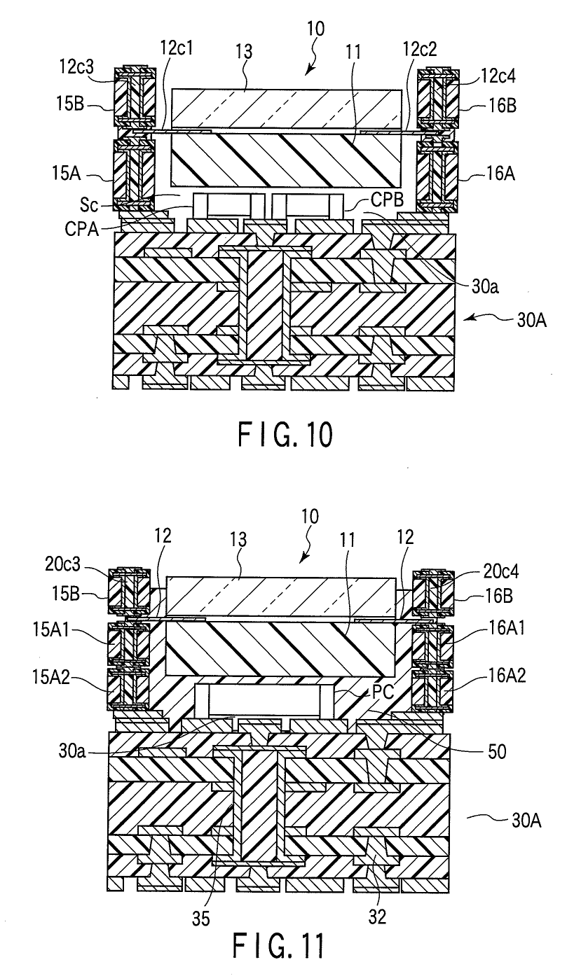

FIG. 10 shows the structure of a small-size module according to a fifth embodiment of the present invention. According to the small-size module structure of the fifth embodiment shown in FIG. 10, a component mounting space Sc is secured between the bottom face of the IC chip 10 and the component mounting face 30a of the multilayer circuit substrate 30A, and a plurality of circuit components CPA, CPB are disposed in the component mounting space Sc and mounted on the component mounting face 30a. In the small-size module structure shown in FIG. 10, the thickness or amount of projection from the lower face of the IC chip main body 11 of a printed wiring board for use as the terminal stud substrates 15A, 16A is selected according to the size (height) of the circuit components CPA, CPB to be mounted, so as to form a component mounting space Sc suitable for the sizes of the circuit components CPA, CPB to be mounted. Adopting such an IC chip mounting structure achieves high density mounting of the circuit components on the small-size module.

FIG. 11 shows the structure of a small-size module according to a sixth embodiment of the present invention. According to the small-size module structure of the sixth embodiment shown in FIG. 11, a component mounting space for a circuit component PC to be mounted on the component mounting face 30a is secured between the bottom face of the IC chip 10 and the component mounting face 30a of the multilayer circuit substrate 30A as shown in FIG. 10, and the circuit component PC is mounted on the component mounting face 30a of the component mounting space. According to the small-size module structure shown in FIG. 11, two terminal stud substrates 15A1, 15A2 and 16A1, 16A2 are stacked, respectively, according to the height of the circuit component PC to be mounted on the component mounting face 30a so as to form a component mounting space suitable for the size of the circuit component PC to be mounted on the component mounting face 30a. Adopting such an IC chip mounting structure can achieve high density mounting of the circuit components in the small-size module like the fifth embodiment. Further, in the small-size module structure of the sixth embodiment, the component mounting space in which the circuit component PC is mounted is filled with the underfill 50 so that the component mounting space is sealed with resin so as to improve the IC chip mounting strength. In the meantime, in the respective embodiments, the through conductors (conductors 20c3, 20c4 shown in FIG. 6, for example) formed in the terminal stud substrates 15B, 16B can be used as an external connecting terminal of the IC chip 10.

FIGS. 12 to 16 show manufacturing and mounting processes for the terminal stud substrates 15A, 15B, 16A, 16B. Here, a case of forming the terminal stud substrates 15A, 16A with a single 4-layer printed wiring board A and then forming the terminal stud substrates 15B, 16B with another 4-layer printed wiring board B is exemplified.

In process 1 shown in FIG. 12, the 4-layer printed wiring board A is cut along cut lines CL1, CL2 to separate a substrate A1 and a substrate A2 containing a small pieces SP1, SP2. The small pieces SP1, SP2 are used later as the terminal stud substrates 15A, 16A. The substrate portions A1, A2 cut off along the cut lines CL1, CL2 other than the small pieces SP1, SP2 are handled as waste materials.

In process 2 shown in FIG. 13, the 4-layer printed wiring board B is cut along the cut lines CL1, CL2 like the process 1 shown in FIG. 12 to separate a substrate B1 and a substrate B2 containing a small piece SP3 and a small piece SP4 which are used as the terminal stud substrates 15B, 16B. The substrate portions B1, B2 cut off along the cut lines CL1, CL2 other than the pieces SP3, SP4 are handled as waste materials.

In process 3 shown in FIG. 14, the substrates A1, A2 cut in the above process 1 of FIG. 12 are set on a jig (not shown) and the IC chip 10 attached to a film 9 is set on the substrates A1, A2. In this case, the IC chip 10 is positioned at a position bridging between the substrates A1 and A2.

In process 4 shown in FIG. 15, the substrates B1, B2 cut off in the process 2 are set on the film 9 set in the process 3 and then, the substrates A1, A2 overlapped on the jig and the substrates B1, B2 are cut along the cut lines CL1, CL2 with the aforementioned small pieces SP1-SP4 left. These small pieces SP1-SP4 are used as the terminal stud substrates 15A, 15B, 16A, 16B. The substrates A1, A2, B1, B2 cut off along the cut lines CL1, CL2 other than the small pieces SP1-SP4 are handled as waste materials.

In process 5 shown in FIG. 16, with the leads 12a1, 12a2, . . . 12e2 of the IC chip 10 nipped by the terminal stud substrates 15A, 15B and 16A, 16B, the terminal stud substrates 15A, 15B and 16A, 16B are heated and pressed. By thermal compression bonding at the time of heating and pressing, the leads 12a1, 12a2, . . . 12e2 of the IC chip 10 are nipped and bonded conductively to the through conductors 20a1, 20a2, . . . 20e2 formed in the terminal stud substrates 15A, 15B and 16A, 16B. Each of the pairs of the terminal stud substrates 15A, 15B and 16A, 16B is provided integrally beside each of the opposite sides of the IC chip main body 11. Because this heating/pressing process has been already described with reference to FIGS. 4 and 5, a simplified drawing is shown here.

As described above, in the small-size module structure of the embodiments of the present invention, the respective leads 12a1, 12a2, . . . 12e2 of the IC chip 10 are thermally compression bonded through the pairs of the terminal stud substrates 15A, 15B and 16A, 16B and soldered to the component mounting face 30a of the circuit substrates 30 (30A, 30B) through the terminal stud substrates 15A, 16A. Thus, as compared with the conventional structure in which the leads are bonded to a circuit directly by heating, thermal damage given to the IC chip main body 11 can be reduced considerably, when the leads are bonded by heating. Further, as compared with conventional mounting means for avoiding thermal influences on the IC chip main body by extending the leads directly or indirectly, the length of the lead extending from the IC chip main body 11 can be reduced according to the present invention, whereby the mounting space for the IC chip 10 on the component mounting face 30a of the circuit substrate 30 can be reduced. Consequently, the smaller size of the module can be achieved easily. Further, the IC chip 10 is mounted on the component mounting face 30a of the circuit substrate 30 with the respective leads 12a1, 12a2, . . . 12e2 of the IC chip 10 supported by the pairs of the terminal stud substrates 15A, 15B and 16A, 16B provided independently on each of the two opposite sides. Therefore, as compared with a single plate or a frame structure provided with an opening which serves as a relief hole or recess for holding the IC chip main body, distortion due to residual stress can be reduced, thereby maintaining a stabilized circuit bonding condition resisting thermal deformation, mechanical stress and the like of the circuit substrate after the IC chip is mounted. Further, because the IC chip 10 can be easily sealed with resin using the terminal stud substrates 15A, 15B and the terminal stud substrates 16A, 16B, miniaturization of the substrate in the small-size module and intensified density of the circuit can be achieved and the IC chip mounting strength can be improved.

While certain embodiments of the invention have been described, these embodiments have been presented by way of example only, and are not intended to limit the scope of the invention. Indeed, the novel methods and systems described herein may be embodied in a variety of forms; furthermore, various omissions, substitutions and changes in the form of the methods and systems described herein may be made without departing from the spirit of the invention. The accompanying claims and their equivalents are intended to cover such forms or modifications as would fall within the scope and spirit of the invention.

What is claimed is:

1. A small-size module comprising:
an Integrated Circuit (IC) chip having leads provided on at least two sides of the IC chip;
a circuit substrate having a component mounting face;
a plurality of pairs of auxiliary substrates disposed between the component mounting face and the IC chip, and configured to hold the leads extending from each of the sides of the IC chip and to allow the IC chip to mount the component mounting face of the circuit substrate; and
a through conductor provided in at least one of the pair of the auxiliary substrates and bonded conductively to the nipped leads to connect the leads to the circuit substrate.

2. The small-size module of claim 1, wherein the IC chip is supported by the auxiliary substrates and has a predetermined gap between the IC chip and the component mounting face.

3. The small-size module of claim 1, wherein the IC chip comprises a rectangular main body and a plurality of leads extending from at least parallel two sides of the main body, and each lead is nipped by the pair of the auxiliary substrates on each side of the IC chip so that the main body is mounted on the component mounting face.

4. The small-size module of claim 1, wherein the auxiliary substrates provided at least on both sides of the IC chip are projected from a bottom face of the IC chip, and a gap is formed between the bottom face of the IC chip and the component mounting face by mounting auxiliary substrates on the component mounting face of the circuit substrate.

5. The small-size module of claim 1, wherein the auxiliary substrates provided at least on both sides of the IC chip are configured to nip front end portions of the IC chip leads in order to form a gap between the IC chip and the auxiliary substrates.

6. The small-size module of claim 1, wherein the IC chip is sealed with resin in a space portion formed among the plurality of pairs of the auxiliary substrates on the component mounting face.

7. The small-size module of claim 1, wherein the circuit substrate is constructed of a multilayer printed wiring board comprising an incorporated component in inner layers of the printed wiring board and at least one of the leads is connected to the incorporated component through the through conductor.

8. The small-size module of claim 4, wherein a circuit component is mounted in the gap formed between the bottom face of the IC chip and the component mounting face.

9. The small-size module of claim 1, wherein the lead comprises a metal bump at a bonding portion bonded to the through conductor connected to the circuit substrate, and the lead is connected conductively to the through conductor by thermal compression bonding through the metal bump and a conductive bonding member.

10. The small-size module of claim 1, wherein the IC chip is a solid state image pickup device with a transparent member disposed on the surface of the IC chip while a part of an end portion of the auxiliary substrate is projected from the transparent member.
